(19) United States
(12) Patent Application Publication
(10) Pub. No.: US 2026/0053000 A1
(43) Pub. Date: Feb. 19, 2026

(54) SEMICONDUCTOR PACKAGE ASSMEBLY AND METHOD FOR FORMING THE SAME

(71) Applicant: STATS ChipPAC Pte. Ltd., Singapore (SG)

(72) Inventors: YoungIn CHOI, Chungcheongbuk-do (KR); SuPin LEE, Incheon (KR); JiNa SONG, Gyeonggi-do (KR)

(21) Appl. No.: 19/300,679

(22) Filed: Aug. 15, 2025

(30) Foreign Application Priority Data
Aug. 16, 2024 (CN) 202411125172.1

(51) Int. Cl. H01L 23/64; H01L 21/48; H01L 21/56; H01L 23/00; H01L 23/31; H01L 23/367; H01L 23/498

(52) U.S. Cl. CPC H01L 23/645; H01L 21/4853; H01L 21/4882; H01L 21/56; H01L 23/3121; H01L 23/367; H01L 23/49811; H01L 24/32; H01L 2224/32245

(57) ABSTRACT

A semiconductor package assembly, comprising: a semiconductor package comprising: a semiconductor die mounted on a substrate; a pair of interconnection blocks mounted at opposite sides of the semiconductor die; and an encapsulant layer, wherein the pair of interconnection blocks have respective top surfaces exposed and a top surface of the semiconductor die is exposed; and an inductor block mounted on the semiconductor package, comprising: an inductor extending through the insulation body in a horizontal direction, and having a pair of inductor contact pads exposed at a bottom surface of the insulation body, wherein the pair of inductor contact pads are aligned to and electrically coupled to the pair of interconnection blocks; and a thermally conductive coating formed at an outer surface of the insulation body and extending in a vertical direction of the insulation body from the bottom surface to a top surface of the insulation body.

### TECHNICAL FIELD

The present application generally relates to manufacture of semiconductor devices, and more particularly, to semiconductor package assembly and method for forming the same.

### BACKGROUND OF THE INVENTION

The semiconductor industry is constantly faced with complex integration challenges as consumers want their electronics to be smaller, faster and higher performance with more and more functionality packed into a single device. In some devices, a semiconductor package is integrated together with an inductor in the form of an assembly, and magnets in the inductor may have a limited heat dissipation ability. Therefore, for such semiconductor package assembly the overall heat dissipation ability may be limited, which may harm its performance due to heat accumulated during operation.

Thus, there exists a need for a semiconductor package assembly with an improved heat dissipation ability.

### SUMMARY OF THE INVENTION

An objective of the present application is to provide a semiconductor package assembly with an improved heat dissipation ability.

According to an aspect of the present application, a semiconductor package assembly is provided. The semiconductor package assembly comprises: a semiconductor package comprising: a substrate; a semiconductor die mounted on the substrate; a pair of interconnection blocks mounted on the substrate and at opposite sides of the semiconductor die; and an encapsulant layer formed on the substrate to encapsulate the semiconductor die and the pair of interconnection blocks, wherein the pair of interconnection blocks have respective top surfaces exposed from the encapsulant layer and a top surface of the semiconductor die is exposed from the encapsulant layer; and an inductor block mounted on the semiconductor package, wherein the inductor block comprises: an insulation body; an inductor extending through the insulation body in a horizontal direction of the insulation body, and having a pair of inductor contact pads exposed at a bottom surface of the insulation body, wherein the pair of inductor contact pads are aligned to and electrically coupled to the pair of interconnection blocks; and a thermally conductive coating formed at an outer surface of the insulation body and extending in a vertical direction of the insulation body from the bottom surface to a top surface of the insulation body, wherein the thermally conductive coating is thermally coupled to the semiconductor die to allow dissipation of heat generated by the semiconductor die through the thermally conductive coating.

According to another aspect of the present application, a method for forming a semiconductor package assembly is provided. The method comprises: providing a substrate; mounting a semiconductor die and a pair of interconnection blocks on the substrate, wherein the pair of interconnection blocks are mounted at opposite sides of the semiconductor die; forming an encapsulant layer on the substrate to encapsulate the semiconductor die and the pair of interconnection blocks but expose respective top surfaces of the pair of interconnection blocks and a top surface of the semiconductor die; providing an inductor block, wherein the inductor block comprises: an insulation body; an inductor extending through the insulation body in a horizontal direction of the insulation body, and having a pair of inductor contact pads exposed at a bottom surface of the insulation body; and a thermally conductive coating formed at an outer surface of the insulation body and extending in a vertical direction of the insulation body from the bottom surface to a top surface of the insulation body; and mounting the inductor block on the encapsulant layer such that the pair of inductor contact pads are aligned to and electrically coupled to the pair of interconnection blocks, and the thermally conductive coating is thermally coupled to the semiconductor die to allow dissipation of heat generated by the semiconductor die through the thermally conductive coating.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A illustrates a cross-sectional view of a semiconductor package assembly according to an embodiment of the present application.

FIG. 1B illustrates a perspective view of an inductor block according to an embodiment of the present application.

FIG. 1C illustrates a top view of the inductor block shown in FIG. 1B.

FIG. 1D illustrates a front view of the inductor block shown in FIG. 1B.

FIG. 1E illustrates a bottom view of the inductor block shown in FIG. 1B.

FIG. 2 illustrates a perspective view of an inductor block according to another embodiment of the present application.

FIGS. 3A to 3F illustrate steps for forming a semiconductor package assembly according to an embodiment of the present application.

FIGS. 4A to 4C illustrate steps for forming solder paste and thermal interface material layer according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

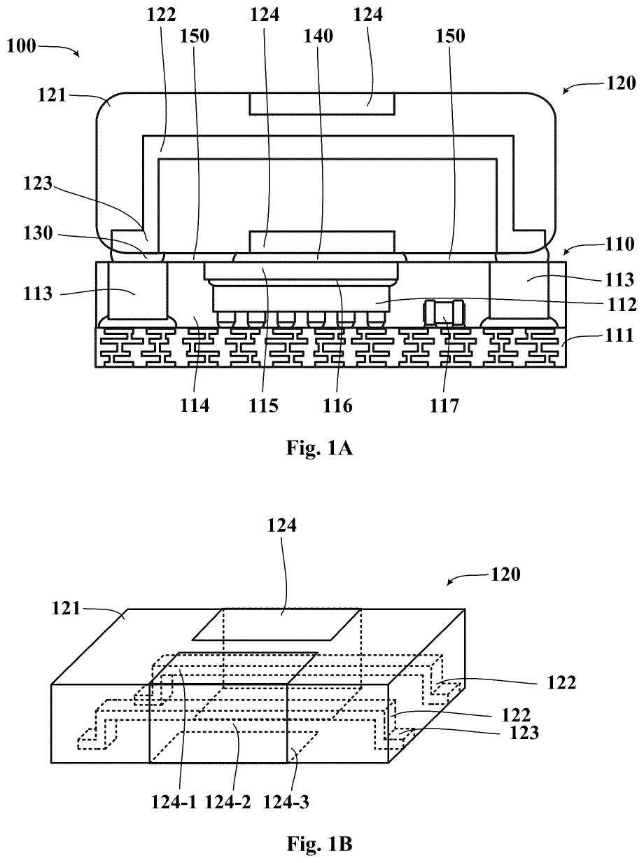

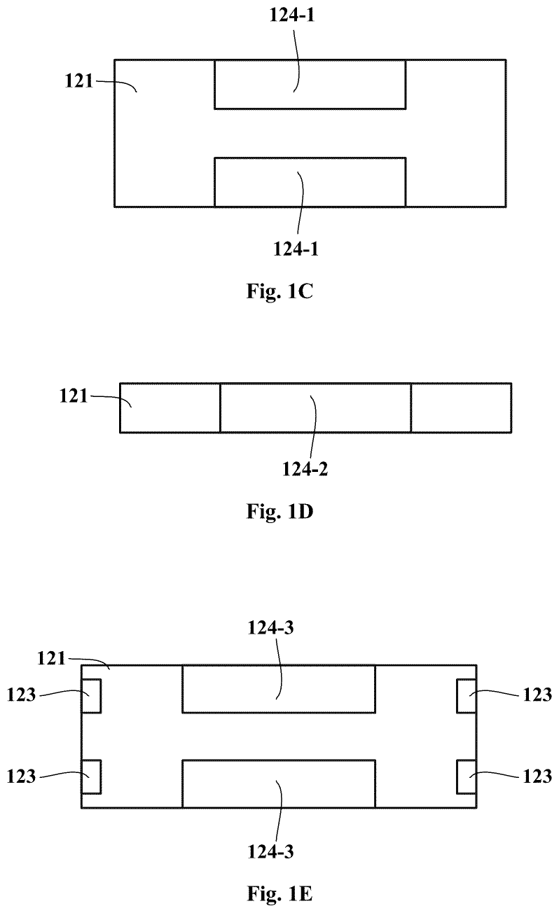

FIG. 1A illustrates a cross-sectional view of a semiconductor package assembly 100 according to an embodiment of the present application. FIG. 1B illustrates a perspective view of an inductor block 120 of the semiconductor package assembly 100 according to an embodiment of the present application. FIGS. 1C to 1E show views from different perspectives of the inductor block 120.

Referring to FIG. 1A, the semiconductor package assembly 100 generally includes a semiconductor package 110, and an inductor block 120 mounted on the semiconductor package 110. In particular, the semiconductor package 110 includes a substrate 111, a semiconductor die 112 mounted on the substrate 111, and a pair of interconnection blocks 113 mounted at opposite sides of the semiconductor die 112. In some embodiments, other electronic components 117 can also be mounted on the substrate 111 as desired.

The substrate 111 may be a multi-layer structure, and the multi-layer structure may include multiple insulating or passivation layers and multiple conductive layers formed over or between the insulating layers. The substrate 111 may include one or more laminated layers of polytetrafluoroethylene pre-impregnated, FR-4, FR-1, CEM-1, or CEM-3 with a combination of phenolic cotton paper, epoxy, resin, woven glass, matte glass, polyester, and other reinforcement fibers or fabrics. The insulating layers may contain one or more layers of silicon dioxide (SiO₂), silicon nitride (Si₃N₄), silicon oxynitride (SiON), tantalum pentoxide (Ta₂O₅), aluminum oxide (Al₂O₃), or other material having similar insulating and structural properties. The substrate 111 can also be a multi-layer flexible laminate, ceramic, copper clad laminate, glass, or semiconductor wafer including an active surface containing one or more transistors, diodes, and other circuit elements to implement analog circuits or digital circuits. The substrate 111 may include one or more electrically conductive layers or redistribution layers (RDL) formed using sputtering, electrolytic plating, electroless plating, or other suitable deposition process.

The semiconductor die 112 may take different forms and may have different functionality as desired. In some embodiments, the semiconductor die 112 may be a power module including one or more insulated gate bipolar transistor(s) (IGBT), one or more metal oxide semiconductor field effect transistor(s) (MOSFET), or one or more gate turn-off thyristor(s) (GTO). In some embodiments, the semiconductor die 112 may be a power supply integrated circuit that integrates at least a driver circuit and one or more MOSFET transistor(s). In such cases, the semiconductor die 112 may generate a relatively large amount of heat and requires efficient heat dissipation.

The pair of interconnection blocks 113 may take different forms and be made of different materials as desired. Preferably, each of the pair of interconnection blocks 113 may be made of one or more metal materials which have good thermal conductivity, such that the pair of interconnection blocks 113 may provide optimal heat conduction as well as structural support. More preferably, each of the pair of interconnection blocks 113 may be a Cu block.

An encapsulant layer 114 is formed on the substrate 111 to encapsulate the semiconductor die 112 and the pair of interconnection blocks 113. In some embodiments, the encapsulant layer 114 can be a polymer composite material, such as epoxy resin, epoxy acrylate, or any suitable polymer with or without filler. The encapsulant layer 114 may be non-conductive, provide structural support, and environmentally protect the electronic devices therein from external environment and contaminants. The encapsulant layer 114 may be formed with any shape as desired. The encapsulant layer 114 may be formed by depositing an encapsulant or molding compound on the substrate 111 using injection molding, compressive molding, transfer molding, liquid encapsulant molding, vacuum lamination, spin coating, or another suitable processes.

Specifically, top surfaces of the pair of interconnection blocks 113 and a top surface of the semiconductor die 112 are exposed from the encapsulant layer 114, such that electrical connection or heat dissipation directly from the respective top surfaces can be achieved.

The configuration of the encapsulant layer 114 and the semiconductor package 112 can vary as desired. In some embodiments, the semiconductor package 112 may have other components mounted thereon, and the top surface of the semiconductor package 112 may be indirectly exposed from the encapsulant layer 114. For example, as shown in FIG. 1A, a heat sink 115 is attached on the top surface of the semiconductor die 112, optionally via a thermal interface material layer 116 formed between the heat sink 115 and the semiconductor die 112, and the heat sink 115 may be at least partially exposed from the encapsulant layer 114, such that heat generated from the semiconductor die 112 may be dissipated via the thermal interface material layer 116 and the heat sink 115 to the external environment or further components.

The heat sink 115 and the thermal interface material layer 116 may take an area generally the same as the top surface of the semiconductor die 112. In some embodiments, the heat sink 115 may be made of the same material as the pair of interconnection blocks 113. Preferably, the heat sink 115 is made of Cu. In some embodiments, the thermal interface material layer 116 can be made of one or more thermally conductive, dispensable materials, preferably thermal greases, thermal adhesives, thermal gap fillers, liquid metal, and solder paste. In another embodiment, the thermal interface material layer 116 includes solder paste which has improved thermal conductivity over typical thermal interface materials. In some other alternative embodiments, the semiconductor package 112 may have a height generally the same as the pair of interconnection blocks 113, and a top surface of the semiconductor package 112 may be directly exposed from the encapsulant layer 114. In other words, there may be no heat sink and thus the thermal interface material layer formed on the top surface of the semiconductor package 112.

The inductor block 120 is mounted on the semiconductor package 110. Specifically, the inductor block 120 may include an insulation body 121 and an inductor 122 extending through the insulation body 121. In some embodiments, the insulation body 121 is formed of a magnetic molding compound and the inductor 122 is molded within the insulation body 121. The insulation body 121 may provide high voltage resistance of inductor parts with a large concentration of highly permeable metal powder. In some embodiments, the insulation body 121 is made of a ferrite material.

The inductor 122 may take any form and material as desired. In some embodiments, the inductor 122 may be an inductor clip. Specifically, the inductor 122 may have a pair of inductor contact pads 123 exposed at a bottom surface of the insulation body 121. As shown in FIG. 1A, the pair of the inductor contact pads 123 are such positioned that they are aligned to the pair of interconnection blocks 113. Additionally, each inductor contact pad 123 may be electrically coupled together with one of the interconnection blocks 113 such as via direct contact or solder paste 130, and therefore, the inductor 122 may achieve electrical connection to the substrate 111 and other electronic components, such as the semiconductor die 112, via the pair of interconnection blocks 113.

As shown in FIGS. 1A to 1E, a thermally conductive coating 124 is formed on an outer surface of the insulation body 121 to assist heat dissipation. Specifically, the thermally conductive coating 124 is formed to be in thermal contact with the semiconductor die 112 underneath. Also, the thermally conductive coating 124 may at least partially extend in a vertical direction of the insulation body 121 from the bottom surface to the top surface of the insulation body 121.

In an embodiment, as shown in FIG. 1A to 1E, the inductor block 120 may include two inductors 122, and each inductor may have a corresponding thermally conductive coating portion formed to surround the inductor. In some embodiments, as shown in FIG. 1B, the thermally conductive coating portions corresponding to different inductors may be separated from each other to avoid undesired thermal crosstalk. In some other embodiments, the thermally conductive coating portions may be a continuous coating instead of segmented coatings.

The thermally conductive coating 124 with respect to the inductors 122 may be positioned to efficiently use the bottom surface of the insulation body 121, as well as to achieve optimal heat dissipation. Preferably, the inductors 122 may be symmetrically arranged to extend horizontally, such as along a longer side of the insulation body 121, and the two thermally conductive coating portions may be symmetrically formed relative to a central line of the insulation body 121 extending in the inductors' extension direction. Each thermally conductive coating portion may be formed with multiple sub-portions. For example, as shown in FIG. 1B, the front thermally conductive coating portion may include a sub-portion 124-1 on the top surface of the insulation body 121, a sub-portion 124-2 on the front surface of the insulation body 121, and a sub-portion 124-3 on the bottom surface of the insulation body 121. The sub-portion 124-1 may assist heat dissipation to an external environment vertically over the inductor block 120. In some embodiments, another heat spreader may be arranged on top of the sub-portion 124-1 to further assist heat dissipation. The sub-portion 124-2 may assist heat dissipation to an external environment at a side of the inductor block 120. And the sub-portion 124-3 may be arranged to be in thermal contact with the semiconductor die 112 underneath. Such arrangement may allow heat generated by the semiconductor die 112 to be dissipated in various directions to the external environment via a relatively large area. Also, as shown in the bottom view of FIG. 1E, in such arrangement, the pair of inductor contact pads 123 are located at both ends of the longer side of the insulation body 121, while the sub-portion 124-3 takes a relatively central position and most of the area of the bottom surface of the insulation body 121. Preferably, a width of the thermally conductive coating 124 in the horizontal direction of the insulation body 121 may be between 50% and 100% of a length of the inductor 122 in the horizontal direction of the insulation body 121. Therefore, the area of the bottom surface of the insulation body 121 is efficiently used, and an area for thermal contact between the thermally conductive coating 124 and the semiconductor die 112 is relatively large. It can also be understood that, the thermally conductive coating 124 may also help dissipate heat accumulated inside the insulation body 121.

The heat conduction from the semiconductor die 112 to the thermally conductive coating 124 may vary according to the specific structure of the semiconductor package assembly 100. In some embodiments, as shown in FIG. 1A, the semiconductor package 110 may include the thermal interface material layer 116 and the heat sink 115 on the top surface of the semiconductor die 112. On the heat sink 115, a thermal interface material layer 140 may be disposed. Therefore, heat generated by the semiconductor die 112 can be conducted via the thermal interface material layer 116, the heat sink 115, and the thermal interface material layer 140 to the thermally conductive coating 124 and be dissipated therethrough.

In some other embodiments (not shown), a top surface of the semiconductor die 112 may be directly exposed from the encapsulant layer 114, the inductor block 120 may be in direct contact with the semiconductor package 110, and the thermally conductive coating 124 may be in direct contact with the top surface of the semiconductor die 112. In this case, heat generated by the semiconductor die 112 may be conducted directly to the thermally conductive coating 124, and heat may be dissipated therethrough.

The thermally conductive coating 124 may be made of any suitable material for heat dissipation. Preferably, the thermally conductive coating 124 may be made of metal, such as Cu, Al, Ag or metal alloy. Preferably, the thermally conductive coating 124 is made of Cu.

In some embodiments, in order to improve the reliability of connection between the inductor block 120 and the semiconductor package 110, an under-fill material layer 150 may be formed between the bottom surface of the insulation body 121 and the top surface of the encapsulant layer 114. In some embodiments, the under-fill material layer 150 may be formed of an encapsulant material. Such under-fill material layer 150 may fill in a gap between the inductor block 120 and the semiconductor package 110 which is not occupied by the solder paste 130 and the optional thermal interface material layer 140. The under-fill material layer 150 may advantageously minimize the coefficient of thermal expansion between the two components connected by the under-fill material layer 150, increase the solder joint reliability, and structurally protect the semiconductor die 112.

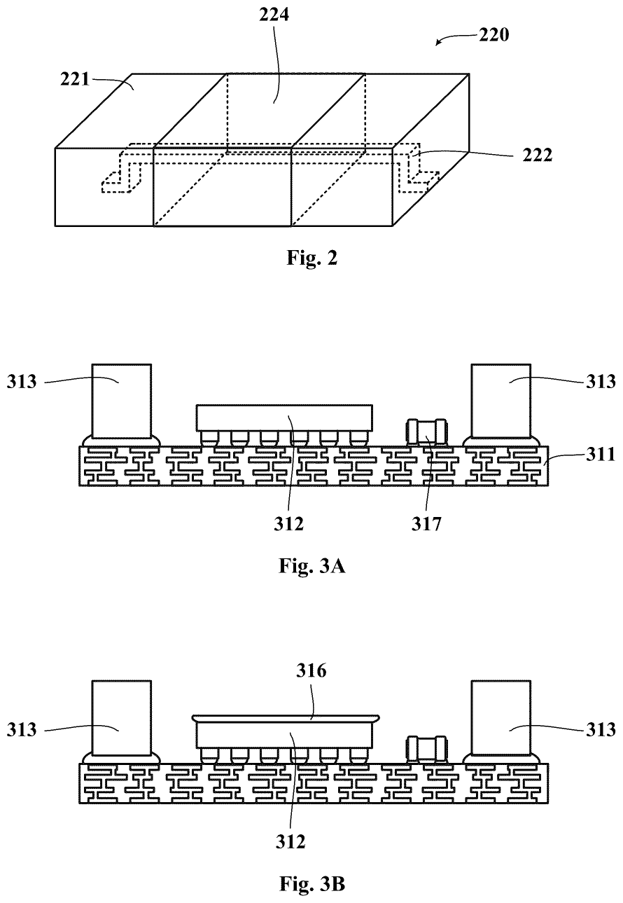

The configuration of the inductor and the thermally conductive coating of the inductor block may vary as desired. For example, as shown in FIG. 2, the inductor block 220 may include one inductor 222 molded within the insulation body 221. The thermally conductive coating 224 may be formed to continuously surround the inductor 222. It can be understood that, the number, position and form of the inductor and the thermally conductive coating may vary as desired.

The present semiconductor package assembly may improve the power density, efficiency and thermal performance, which results in improved overall performance, especially when it is used in applications where power consumption is high and/or signal processing is continuous, such as in a server.

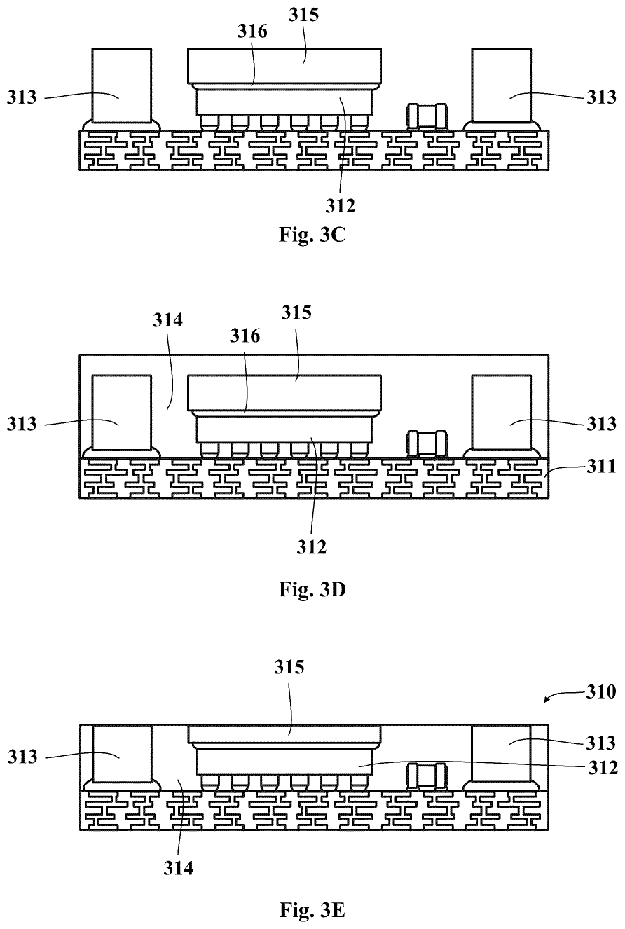

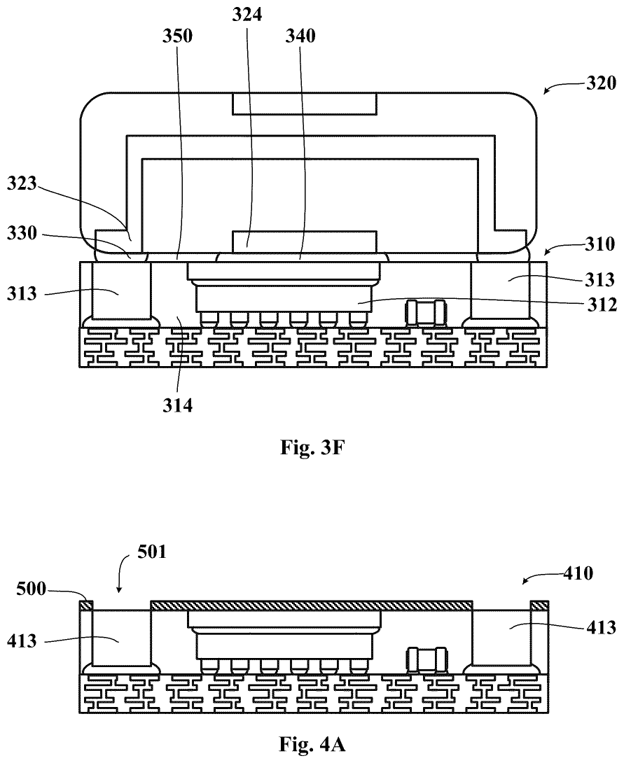

FIGS. 3A to 3F illustrate steps of a method for forming a semiconductor package assembly according to an embodiment of the present application. For example, the method may be used to form the semiconductor package assembly shown in FIGS. 1A to 1E.

Referring to FIG. 3A, a substrate 311 is provided, and a semiconductor die 312 and a pair of interconnection blocks 313, and optionally, an electronic component 317 are mounted on the substrate 311, wherein the pair of interconnection blocks 313 are mounted at opposite sides of the semiconductor die 312.

In some embodiments, a height difference between the semiconductor die 312 and the pair of interconnection blocks 313 may be relatively large, and additional components may be disposed on the semiconductor die 312 to make up the height difference. For example, as shown in FIG. 3B, a thermal interface material layer 316 may be formed on the semiconductor die 312. The thermal interface material layer 316 can be made of thermally conductive, dispensable materials, preferably thermal greases, thermal adhesives, thermal gap fillers, liquid metal, and solder paste. The thermal interface material layer 316 may be formed with any suitable process, for example dispensing a thermal interface material, CVD, PVD, etc. Then, referring to FIG. 3C, a heat sink 315 may be attached on the thermal interface material layer 316 on the top surface of the semiconductor die 312. The heat sink 315 may be made of metal, such as Cu, such that heat generated by the semiconductor die 312 may be conducted upwards through the heat sink 315. After the heat sink 315 is attached, a top surface of the heat sink 315 may or may not level with a top surface of the pair of interconnection blocks 313.

Referring to FIG. 3D, an encapsulant layer 314 is formed on the substrate 311 to encapsulate the semiconductor die 312 and the pair of interconnection blocks 313, the thermal interface material layer 316 and the heat sink 315. The components may be fully encapsulated.

Referring to FIG. 3E, a grinding process may be performed to at least partially expose a top surface of the pair of interconnection blocks 313 and a top surface of the heat sink 315 to the external environment. It can be understood that, in this case, a top surface of the semiconductor die 312 is free from and indirectly exposed from the encapsulant layer 314. After the grinding process, a semiconductor package 310 is formed, and electrical connection from an inductor block to be attached above the semiconductor package 310 to the pair of interconnection blocks 313 may be achieved, and thermal conduction from the semiconductor die 312 via the heat sink 315 to the inductor block to be attached above the semiconductor package 310 may be achieved.

It can be understood that, in some other embodiments, the encapsulant layer 314 may be firstly formed, then a laser ablation process may be adopted to form a cavity on the semiconductor die, and then the thermal interface material layer 316 and the heat sink 315 may be formed.

It can also be understood that, in some other embodiments, a height of the pair of interconnection blocks 313 and a height of the heat sink 315 can be determined in advance such that after the heat sink 315 is attached on the semiconductor die 312, a top surface of the pair of interconnection blocks 313 and the top surface of the heat sink 315 may level with each other. In such cases, a film-assisted molding process may be adopted, and no grinding process would be needed.

It can also be understood that, in some embodiments, the formation of the semiconductor package 310 may be carried out in a wafer-level, and the semiconductor package 310 and other similar packages may be singulated from a substrate strip before an inductor block is mounted on each of the semiconductor packages. In the case where a height of the inductor block is relatively large and the inductor block may be tilted after being mounted on the semiconductor package 310, the risk of the inductor block being damaged during singulation is reduced.

Referring to FIG. 3F, after the formation of the semiconductor package 310, an inductor block 320 is provided and mounted on the encapsulant layer 314 of the semiconductor package 310. The configuration of the inductor block 320 may refer to the inductor block 120 illustrated above with reference to FIG. 1A and would not be repeated herein. The inductor block 320 may be positioned, for example via a pick-and-place machine, such that the pair of inductor contact pads 323 are aligned to and electrically coupled to the pair of interconnection blocks 313, and the thermally conductive coating 324 is thermally coupled to the semiconductor die 312 to allow dissipation of heat generated by the semiconductor die 312 through the thermally conductive coating 324.

The configurations at the interface between the semiconductor package 310 and the inductor block 320 may vary as desired. As shown in FIG. 3F, in some embodiments, solder paste 330, a thermal interface material layer 340, and an under-fill material layer 350 may be formed between the inductor block 320 and the semiconductor package 310. The solder paste 330 and the thermal interface material layer 340 may be formed to assist electrical connection and thermal conductivity, respectively. The under-fill material layer 350 may help improve the reliability of the overall structure. The solder paste 330, the thermal interface material layer 340, and the under-fill material layer 350 may be formed via any suitable process. In some embodiments, the thermal interface material layer 340 and the under-fill material layer 350 can also be formed before or after the attachment of the inductor block 320, such as by depositing thermal interface material and encapsulant material in-between the semiconductor package 310 and the inductor block 320, respectively.

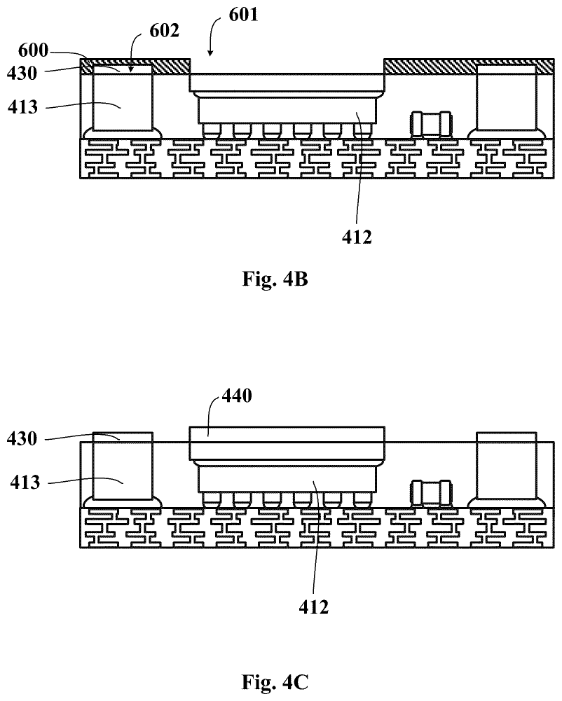

In some embodiments, the solder paste and thermal interface material layer may be formed via a stencil printing process. FIGS. 4A to 4C illustrate steps for forming solder paste and thermal interface material layer according to an embodiment of the present application, which may be alternative to the method shown in FIGS. 3A to 3F.

Referring to FIG. 4A, a stencil 500 may be disposed on the semiconductor package 410. The stencil 500 may have a pair of through holes 501 at a position over the pair of interconnection blocks 413, such that solder paste 430 (shown in FIG. 4B) may be formed in the through holes 501 in a solder paste printing process.

Referring to FIGS. 4B and 4C, a thermal interface material layer may be formed via a stencil printing process with a half-etched stencil 600. Specifically, the half-etched stencil 600 may include a through hole 601 at a position over the semiconductor die 412, and a pair of etched portion 602 at a position of the solder paste 430. Each etched portion 602 may take the form of a blind hole, such that the solder paste 430 may be accommodated within the pair of etched portion 602 and would not be exposed by the half-etched stencil 600. A thermal interface material layer 440 (shown in FIG. 4C) may be formed in the through hole 601 in a thermal interface material printing process.

It can be understood that, with the process described above, the solder paste 430 and the thermal interface material layer 440 may be formed separately without being affected by each other. As illustrated in the aforementioned embodiments, the solder paste 430 may be used for the electrical connection between the pair of interconnection blocks 413 underneath and a pair of inductor contact pads of an inductor block to be mounted above, and the thermally conductive coating 440 may be used for thermal conduction from the semiconductor die 412 underneath to a thermally conductive coating of an inductor block to be mounted above.

The discussion herein included numerous illustrative figures that showed various portions of a semiconductor package assembly and method for forming the same. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor package assembly, comprising:
a semiconductor package comprising:
a substrate;
a semiconductor die mounted on the substrate;
a pair of interconnection blocks mounted on the substrate and at opposite sides of the semiconductor die; and
an encapsulant layer formed on the substrate to encapsulate the semiconductor die and the pair of interconnection blocks, wherein the pair of interconnection blocks have respective top surfaces exposed from the encapsulant layer and a top surface of the semiconductor die is exposed from the encapsulant layer; and
an inductor block mounted on the semiconductor package, wherein the inductor block comprises:
an insulation body;
an inductor extending through the insulation body in a horizontal direction of the insulation body, and having a pair of inductor contact pads exposed at a bottom surface of the insulation body, wherein the pair of inductor contact pads are aligned to and electrically coupled to the pair of interconnection blocks; and
a thermally conductive coating formed at an outer surface of the insulation body and extending in a vertical direction of the insulation body from the bottom surface to a top surface of the insulation body, wherein the thermally conductive coating is thermally coupled to the semiconductor die to allow dissipation of heat generated by the semiconductor die through the thermally conductive coating.

2. The semiconductor package assembly of claim 1, the semiconductor package further comprising:
a heat sink attached on the top surface of the semiconductor die and exposed from the encapsulant layer, and
a thermal interface material layer formed between the heat sink and the insulation body of the inductor block, such that the semiconductor die is thermally coupled to the thermally conductive coating via the heat sink and the thermal interface material layer.

3. The semiconductor package assembly of claim 1, wherein the insulation body is formed of a magnetic molding compound, and the inductor is molded within the insulation body.

4. The semiconductor package assembly of claim 1, wherein a width of the thermally conductive coating along the horizontal direction of the insulation body is between 50% to 100% of a length of the inductor along the horizontal direction of the insulation body.

5. The semiconductor package assembly of claim 1, wherein the thermally conductive coating comprises a first portion and a second portion which are symmetrically formed relative to a central line of the insulation body extending in the horizontal direction.

6. The semiconductor package assembly of claim 1, further comprising: an under-fill material layer formed between the bottom surface of the insulation body and a top surface of the encapsulant layer.

7. A method for forming a semiconductor package assembly, wherein the method comprises:
providing a substrate;
mounting a semiconductor die and a pair of interconnection blocks on the substrate, wherein the pair of interconnection blocks are mounted at opposite sides of the semiconductor die;
forming an encapsulant layer on the substrate to encapsulate the semiconductor die and the pair of interconnection blocks but expose respective top surfaces of the pair of interconnection blocks and a top surface of the semiconductor die;
providing an inductor block, wherein the inductor block comprises: an insulation body; an inductor extending through the insulation body in a horizontal direction of the insulation body, and having a pair of inductor contact pads exposed at a bottom surface of the insulation body; and a thermally conductive coating formed at an outer surface of the insulation body and extending in a vertical direction of the insulation body from the bottom surface to a top surface of the insulation body; and
mounting the inductor block on the encapsulant layer such that the pair of inductor contact pads are aligned to and electrically coupled to the pair of interconnection blocks, and the thermally conductive coating is thermally coupled to the semiconductor die to allow dissipation of heat generated by the semiconductor die through the thermally conductive coating.

8. The method of claim 7, wherein before mounting the inductor block, the method further comprises: attaching a heat sink on the top surface of the semiconductor die, wherein a top surface of the heat sink is exposed from the encapsulant layer; and
the method further comprises: forming a thermal interface material layer on the heat sink and under the insulation body of the inductor block, such that the semiconductor die is thermally coupled to the thermally conductive coating via the heat sink and the thermal interface material layer.

9. The method of claim 8, wherein before forming a thermal interface material layer, the method comprises:
forming a solder paste on the encapsulant layer, such that the pair of inductor contact pads are electrically coupled to the pair of interconnection blocks via the solder paste; and
wherein when forming a thermal interface material layer, a half etched stencil is used such that the solder paste is accommodated within an etched portion of the half etched stencil.

10. The method of claim 7, wherein the insulation body is formed of a magnetic molding compound, and the inductor is molded within the insulation body.

11. The method of claim 7, wherein a width of the thermally conductive coating along the horizontal direction of the insulation body is between 50% to 100% of a length of the inductor along the horizontal direction of the insulation body.

12. The method of claim 7, wherein the thermally conductive coating comprises a first portion and a second portion which are symmetrically formed relative to a central line of the insulation body extending in the horizontal direction.

13. The method of claim 7, further comprising: forming an under-fill material layer between the bottom surface of the insulation body and a top surface of the encapsulant layer.
